(19) United States
(12) Patent Application Publication
(10) Pub. No.: US 2026/0304670 A1
(43) Pub. Date: Oct. 1, 2026

(54) COMPACT CONNECTORIZED BREAKOUT PANEL

(71) Applicant: Groq, Inc., San Jose, CA (US)

(72) Inventors: Cameron Ferdinands, Brisbane (AU); Matthew Ayre, Sydney (AU)

(21) Appl. No.: 19/554,225

(22) Filed: Mar. 2, 2026

Related U.S. Application Data
(60) Provisional application No. 63/780,695, filed on Mar. 31, 2025.

(51) Int. Cl. H05K 7/14

(52) U.S. Cl. CPC H05K 7/1427; H05K 7/1452

(57) ABSTRACT

A networking panel can include one or more first ports, each first port configured to receive a multi-strand first connector. The networking panel can include a plurality of second ports, each second port configured to receive a second connector. The networking panel can include a plurality of communication strands collectively connecting each respective first port of the one or more first ports to two or more corresponding second ports of the plurality of second ports.

### CROSS-REFERENCE TO PRIORITY APPLICATION

The present patent application claims the benefit of priority to U.S. Provisional Application No. 63/780,695, titled, “COMPACT CONNECTORIZED BREAKOUT PANEL,” filed Mar. 31, 2025, the entirety of which is incorporated by reference herein.

### FIELD

The present disclosure relates generally to systems and methods for communication between computing devices or computing components.

### BACKGROUND

Data centers for performing computations, such as machine learning computations, may contain a large number of computing devices arranged in racks, each rack holding several computing devices. The computing devices or components thereof may be connected to each other via various communication channels, such as via Ethernet links, chip-to-chip communication links, or other communication links. In some instances, installing such communication channels can be expensive and error-prone, particularly for large data centers having a large number of communication channels. Additionally, some communication channel arrangements may take up a large amount of data center space, and may rely on expensive communication components such as active optical switches.

### SUMMARY

Aspects and advantages of embodiments of the present disclosure will be set forth in part in the following description, or can be learned from the description, or can be learned through practice of the embodiments.

Example aspects of the present disclosure provide an example networking panel. In some implementations, the example networking panel can include one or more first ports. In the example networking panel, each first port can be configured to receive a multi-strand connector. The example networking panel can include a plurality of second ports. In the example networking panel, each second port of the plurality of second ports can be configured to receive a connector. The example networking panel can include a plurality of communication strands collectively connecting each respective first port of the one or more first ports to two or more corresponding second ports of the plurality of second ports.

Example aspects of the present disclosure provide an example computing system. In some implementations, the example computing system can include a plurality of computing devices. The example computing system can include one or more networking panels. In the example computing system, each networking panel can include one or more first ports. In the example computing system, each first port can be configured to receive a multi-strand connector. In the example computing system, each networking panel can include a plurality of second ports. In the example computing system, each second port can be configured to receive a connector. In the example computing system, each networking panel can include a plurality of communication strands collectively connecting each respective first port of the one or more first ports to two or more corresponding second ports of the plurality of second ports. In the example computing system, each computing device of the plurality of computing devices can be operatively connected to at least one networking panel of the one or more networking panels.

Example aspects of the present disclosure provide an example method. In some implementations, the example method can include connecting each computing device of a plurality of computing devices to a corresponding networking panel of a plurality of networking panels. In the example method, each networking panel of the plurality of networking panels can include one or more first ports, each first port configured to receive a multi-strand connector. In the example method, each networking panel of the plurality of networking panels can include a plurality of second ports, each second port configured to receive a connector. In the example method, each networking panel of the plurality of networking panels can include a plurality of communication strands collectively connecting each respective first port of the one or more first ports to two or more corresponding second ports of the plurality of second ports. The example method can include connecting each networking panel of the plurality of networking panels to one or more active switches, wherein each active switch of the one or more active switches is configured to be connected to two or more networking panels of the plurality of networking panels.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 is a block diagram of an example networking panel according to example implementations of aspects of the present disclosure;

FIG. 2 is a block diagram of an example networking panel according to example implementations of aspects of the present disclosure;

FIG. 3 is a block diagram of an example system comprising one or more networking panels according to example implementations of aspects of the present disclosure;

FIG. 4 is a block diagram of a portion of an example multi-rack computing system according to example implementations of aspects of the present disclosure;

FIG. 5 is a flow chart diagram of an example method for wiring a data center according to example implementations of aspects of the present disclosure;

FIG. 6 is a flow chart diagram of an example method for fabricating a plurality of network panels according to example implementations of aspects of the present disclosure;

FIG. 7 is a block diagram of an example processor device according to example implementations of aspects of the present disclosure; and

FIG. 8 is a block diagram of an example computing node according to example implementations of aspects of the present disclosure.

### DETAILED DESCRIPTION

Example embodiments according to some aspects of the present disclosure are directed to systems and methods for communication between computing devices. More particularly, example embodiments according to some aspects of the present disclosure include example connectorized breakout panels configured to receive one or more multi-strand communication cables via one or more first ports configured to receive a multi-strand connector; and route signals from each strand of the multi-strand communication cable to a respective port of a plurality of second ports configured to receive a connector (e.g., multi-strand connector, etc.). For example, a networking panel (e.g., connectorized breakout panel, etc.) can include a plurality of communication strands each connecting at least one strand of a multi-strand communication cable to a corresponding second port, wherein the plurality of communication strands collectively divide (e.g., “break out,” etc.) a plurality of signals of the multi-strand communication cable amongst a plurality of second ports.

In some instances, a connectorized breakout panel can include a breakout-breakin panel configured to receive a plurality of multi-strand communication cables via a plurality of first ports; and route signals from each strand of each multi-strand communication cable to a respective port of a plurality of second ports each configured to receive a multi-strand connector, wherein at least one of the second ports is configured to receive strand(s) from each of two or more first ports, and provide signals from the two or more first ports to a single multi-strand connector.

In some instances, example panels according to some aspects of the present disclosure can include a compact panel configured to be inserted into a server rack holding a plurality of computing devices. For example, in some instances, a compact panel can include a panel configured to fit into a server rack space that is smaller than or equal to four rack units (RU); such as smaller than or equal to 2 RU; such as smaller than or equal to 1 RU. As a non-limiting illustrative example, in some instances, a networking panel can include a panel configured to be slotted into a 1RU slot of a networking rack comprising a plurality of networking panels and one or more active optical switches.

In some instances, an example networking panel according to some aspects of the present disclosure can be part of a computing system comprising a plurality of computing devices and one or more (e.g., a plurality of) networking panels (e.g., connectorized breakout panels, etc.) according to aspects of the present disclosure. For example, in some instances, a data center can include a plurality of racks. Each rack of the plurality of racks can hold a plurality of computing devices. Each computing device of the rack can be connected (e.g., via a breakout connector, via a top-of-rack panel, etc.) to one or more strands of a multi-strand communication link (e.g., multi-strand fiber optic cable, etc.). The multi-strand communication link can be connected to a connectorized breakout panel, such as a connectorized breakout panel located in an end-of-row networking rack. The breakout panel can route communications from each strand of the multi-strand communication link to one or more second ports of the breakout panel. In some instances, each second port can be connected to a corresponding port of one or more switches (e.g., active optical switches, etc.) configured to route signals to various routing destinations.

In some instances, an example end-of-row architecture for an example computing system can include one or more dedicated end-of-row networking racks configured to simplify cabling, reduce risk of operator error, or the like. For example, in some instances, an end-of-row networking rack can be configured to reduce (e.g., minimize, etc.) a number or complexity of ports that must be accessed to execute one or more wiring actions (e.g., communication topology reconfigurations, etc.). For example, in some instances, a networking rack can include a fixed-connection rack portion comprising a plurality of first connections (e.g., permanent connections, fixed connections, access-prohibited connections, etc. ; communication cables fixedly connecting pairs of ports, etc.) that are not required to be rearranged or otherwise accessed during one or more wiring operations of interest; a plurality of second connections (e.g., restricted-access connections; semi-permanent or semi-fixed connections, etc.) that are not expected to require reconfiguration for some (e.g., most, etc.) wiring operations of interest or that are associated with a high risk of operator error during reconfiguration; and a plurality of third connections (e.g., reconfigurable connections, connections configured to be readily accessible to data center employees, etc.). In some instances, an end-of-row rack can divide the first, second, and third connections into first, second, and third regions respectively (e.g., contiguous regions; vertical regions, such as a 10RU or other size vertical region for each of the first, second, and third regions). In some instances, a networking rack according to some aspects of the present disclosure can include one or more access restriction devices (e.g., locks, keycard readers, access panels, etc.) configured to limit access to one or more of the first, second, and third regions (e.g., first and second only, etc.). In some instances, a networking architecture and breakout panel can be configured to combine the functionality of a conventional top-of-rack switch and the functionality of a management switch into a single breakout panel with remote 100 Gb/s distribution.

In some instances, an example breakout panel can include a panel configured to receive a plurality of different connector types. For example, in some instances, the one or more first ports (e.g., ports configured to be connected to an end-of-row networking rack, etc.) of an example breakout panel can be configured to receive a first connector having a first type and a second connector having a second type. As another example, in some instances, the plurality of second ports (e.g., ports configured to be connected to computing devices within a rack associated with the breakout panel, etc.) of an example breakout panel can be configured to receive a first connector having a first type and a second connector having a second type. As another example, in some instances, the one or more first ports can be configured to receive a first connector having a first type and the one or more second ports can be configured to receive a second connector having a second type. In some instances, different connector types can include connector types having different bandwidths (e.g., 100 Gb/s (100 G), 400 Gb/s (400 G), 800 Gb/s (800 G), etc.). In some instances, different connector types can include connector types for accepting communication cables with different numbers of strands (e.g., 12-strand MPT-12 connector, 32-strand MPT-32 connector, etc.). In some instances, different connector types can include connector types having different formats or form factors (e.g., multi-fiber push-on (MPO), LC connector, SC connector, very small form factor (VSFF) connector, etc.).

In some instances, an example panel according to some aspects of the present disclosure can include a prefabricated connectorized breakout panel that may be fabricated and tested at a manufacturing facility according to a predetermined connection topology. In some instances, a prefabricated panel can be configured to reduce a complexity of data center installation of the connection topology compared to some alternative implementations (e.g., end-of-row communication topologies implemented without breakout panels, such as by splicing or hand-connecting each individual strand of the topology, etc.). For example, in some instances, a prefabricated panel can be configured to connect to each of a plurality of computing devices via a small number (e.g., one, two, four, etc.; minimum or near-minimum number of connections for a given connection topology; etc.) of multi-fiber connections; and connect to each of one or more switches (e.g., end-of-row active optical switches, etc.) via a small number of multi-fiber connections. In this manner, for instance, a predetermined connection topology can implement the complexities of a predetermined connection topology substantially within a plurality of prefabricated breakout panels, thereby greatly simplifying a data center installation process.

In some instances, connectorized breakout panels according to some aspects of the present disclosure can implement a wide variety of topologies (or portions thereof). In some example implementations, an example topology can include a topology configured to provide communication redundancy or reduce an impact of failure of one or more communication components (e.g., switch failure, cable failure, etc.). For example, in some instances, a panel according to some aspects of the present disclosure can be configured to divide communications to and from a computing device of interest amongst a plurality of communication links, such as amongst a plurality of multi-fiber cables directed to a plurality of ports or switches; or the like.

In some instances, a data center according to aspects of the present disclosure can be wired (e.g., during an initial buildout of the data center; during a rewiring or reconfiguration operations; etc.) by obtaining a plurality of breakout panels according to some aspects of the present disclosure, such as prefabricated breakout panels that route individual strands according to a predetermined connection topology; installing the breakout panels in one or more end-of-row networking racks; connecting each breakout panel to a plurality of compute nodes located in a plurality of racks (e.g., via one multi-strand communication channel per rack, etc.).

Example embodiments according to some aspects of the present disclosure can provide for a number of technical effects and benefits, such as improvements to computing technology (e.g., device-to-device communication technology, etc.). For example, in some instances, systems and methods according to some aspects of the present disclosure can reduce a cost (e.g., time cost, labor cost, financial cost, etc.) of one or more data center wiring operations (e.g., installing or setting up a data center; reconfiguring a network topology; etc.) compared to some alternative implementations (e.g., splicing-based implementations, break-out/break-in implementations without compact connectorized panels, etc.). As another example, in some instances, systems and methods according to some aspects of the present disclosure can reduce an amount of data center space (e.g., rack space, floor space, etc.) required to implement a given connection topology compared to some alternative implementations (e.g., splicing-based implementations, break-out/break-in implementations without compact connectorized panels, etc.). As another example, in some instances, systems and methods according to some aspects of the present disclosure can reduce a cost (e.g., hardware cost, capital cost, installation cost, etc. ; per-port cost of wiring up a plurality of communication ports of a plurality of communication devices, etc.) of device-to-device communication compared to some alternative implementations (e.g., top-of-rack switch implementations, large-port-count single-strand implementations, etc.). As another example, in some instances, systems and methods according to some aspects of the present disclosure can reduce an installation complexity and/or reduce a risk of operator error when implementing (e.g., installing, reconfiguring, etc.) a connection topology compared to some alternative implementations. As another example, in some instances, systems and methods according to some aspects of the present disclosure can greatly reduce (e.g., by an order of magnitude, etc.) a number of components (e.g., switches, cables, etc.) required to implement a given communication topology, thereby greatly reducing an installation complexity compared to some alternative implementations (e.g., hand-connected wiring implementations, etc.).

With reference now to the Figures, example embodiments of the present disclosure will be discussed in further detail.

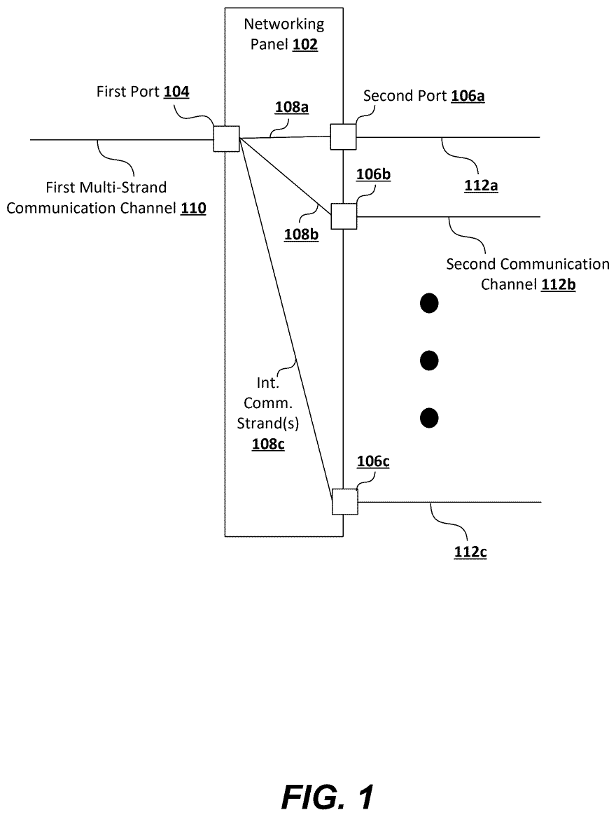

FIG. 1 is a block diagram of an example networking panel 102 according to example implementations of aspects of the present disclosure. A networking panel 102 can include one or more first ports 104 configured to receive a multi-strand connector of a first multi-strand communication channel 110. The networking panel 102 can further include a plurality of second ports 106a, b, c each configured to receive one or more second communication channels 112a, b, c. The networking panel 102 can further include a plurality of internal communication strands 108a, 108b, 108c connecting the first port 104 to a plurality of second ports 106a, b, c. For example, each internal communication strand 108a, b, c can be configured to transmit signals received via a single strand of the multi-strand communication channel 110 to a corresponding destination (e.g., transmit to a corresponding single strand of a second communication channel 112 via a second port 106a, b, c, etc.), or vice versa (e.g., transmit signals received from a single strand of a second communication channel 112 to a corresponding single strand of a first multi-strand communication channel 110, etc.).

A networking panel 102 can include, for example, various types of hardware configured to connect first port(s) 104 to corresponding second ports 106a, b, c. In some instances, a networking panel 102 can include a passive optical routing device configured to route signals from one or more first ports 104 to corresponding second port(s) 106a, b, c. In some instances, a networking panel 102 can include a physical enclosure or housing comprising the first port(s) 104, second ports 106, and internal strands 108. In some instances, a networking panel 102 housing can have various form factors, such as a rack-mount form factor configured to fit a standard-sized server rack (e.g., one-rack-unit (1RU) housing, 2RU housing, 4RU housing, half-RU housing, etc.), or other form factor (e.g., blade form factor, etc.). In some instances, a networking panel 102 can have a size that is less than or equal to four rack units, such as less than or equal to two rack units, such as less than or equal to one rack unit, such as equal to one rack unit.

In some instances, a networking panel 102 can include a prefabricated or pretested panel assembly, which can in some instances reduce a cost of installation or maintenance in a data center. For example, in some instances, a networking panel 102 can include a prefabricated assembly comprising a plurality of internal strands 108 connecting first port(s) 104 to corresponding second ports 106 in a predetermined configuration. In some instances, a plurality of prefabricated networking panels 102 having the same predetermined internal strand 108 routing configuration or different internal strand wiring configurations can be fabricated at a fabrication plant separate from a data center in which the networking panels 102 may be deployed. In some instances, a networking panel 102 can be tested prior to deployment in a data center. For example, in some instances, a networking panel 102 can be tested at a fabrication facility prior to data center deployment, which can in some instances reduce a cost (e.g., labor cost, hardware cost, time cost, etc.) of testing and installation compared to some alternative implementations. In some instances, testing a networking panel 102 can include providing a plurality of test signals to a first port 104 (e.g., via a multi-strand communication channel 110 or multi-strand connector, etc.); measuring the plurality of test signals at a plurality of second ports 106a, b, c; and determining, based on the measurements, whether the networking panel 102 is routing the test signals according to the predetermined configuration. In some instances, a plurality of networking panels 102 (e.g., a plurality of networking panels 102 having the same predetermined routing configuration of internal strands 108, etc.) can be tested in assembly line fashion (e.g., at a fabrication plant, etc.) prior to deployment to a data center.

In some instances, a plurality of networking panels 102 can be tested using a single test harness, such as a test harness comprising one or more hardware, software, or firmware components configured to provide a plurality of test signals to a first port 104 (e.g., signal generator components, communication channel components, multi-strand connector components, etc.) and one or more hardware, software, or firmware components configured to measure a plurality of test signals at a plurality of second ports 106 (e.g., communication channel components, connector components, optical receiver or optical network terminal components, optical power meter components, etc.).

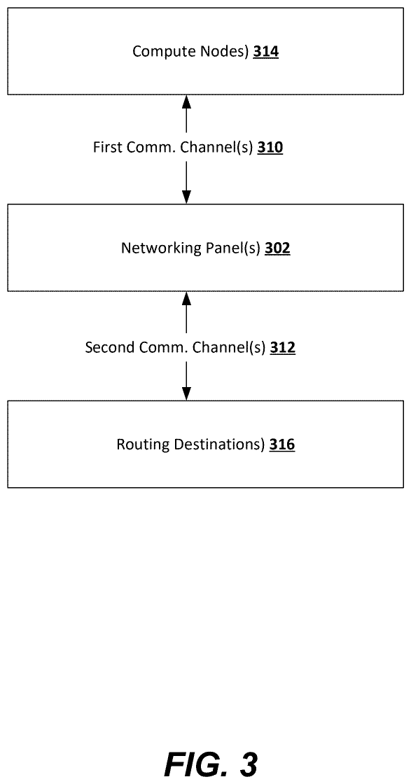

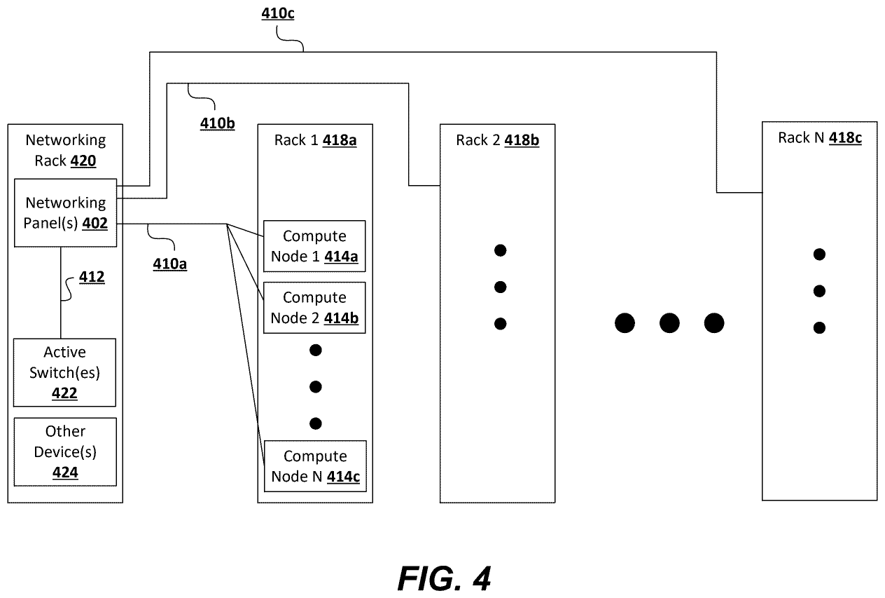

In some instances, a networking panel 102 can be connected to various devices or components (e.g., data center components, etc.) via communication channels 110, 112, such as computing devices, networking devices, or other devices. Further details of some example systems comprising one or more networking panels connected to one or more other devices are provided below with respect to FIGS. 3 and 4.

A first port 104 can be or include one or more hardware components for receiving, transmitting, or otherwise interfacing with one or more communication links. For example, in some instances, a first port 104 can include one or more hardware components configured to connect a first multi-strand communication channel 110 to one or more internal strands 108. In some instances, a first port 104 can include a multi-strand port configured to connect each of a plurality of strands of the first multi-strand communication channel 110 to a corresponding internal strand 108a, b, c of a plurality of internals strands 108 of the networking panel 102. Connecting a strand of a first multi-strand communication channel 110 to a corresponding internal strand 108a, b, c can include, for example, passing one or more first signals (e.g., optical signals, electrical signals, etc.) from the strand of the communication channel 110 to the internal strand 108a, b, c; passing one or more second signals (e.g., optical signals, electrical signals, etc.) from the internal strand 108a, b, c to the strand of the communication channel 110; or both.

In some instances, a first port 104 can include a physical receptacle, socket, or coupling mechanism configured to provide a mechanical and signal connection for a communication connector. In some instances, a first port 104 can include a connectorized port configured to receive a single multi-strand connector of the first multi-strand communication channel 110 and connect to strands of the communication channel via the multistrand connector. Example multi-strand connectors can include high-density optical interfaces, such as multi-fiber push-on (MPO) connectors or multi-fiber termination push-on (MTP) connectors. For example, in some example implementations, the first port 104 can be configured to receive a 24-strand MPO (MPO-24) connector, or another connection type (e.g., 24-strand MTP connector, 12-strand MTP or MPO connector, 32-strand MTP or MPO connector, etc.). In some instances, a networking panel 102 can have a plurality of first ports 104, such as a plurality of connectorized first ports 104 configured to receive the same type of connector (e.g., a plurality of MPO-24 ports, etc.) or different types of connectors.

In some instances, a networking panel 102 can include a plurality of first ports 104 (not expressly depicted in FIG. 1). For example, in some instances, a networking panel 102 can include a number of first ports 104 sufficient to receive more than 100 communication strands (e.g., fiber optic cores, etc.) per networking panel 102, such as more than 200, such as more than 500. As another example, a networking rack comprising a plurality of networking panels 102 can include a number of first ports 104 sufficient to receive more than 1000 communication strands (e.g., fiber optic cores, etc.), such as more than 2000, such as more than 3000, such as more than 4000. Further details of an example multi-rack system comprising a networking rack configured to receive a plurality of communication channels (e.g., a networking rack configured to receive a plurality of communication channels comprising between 2000 and 5000 strands, etc.) are provided below with respect to FIG. 4.

In some instances, a second port 106 can have any property described above with respect to a first port 104. For example, in some instances, a second port 106 can include one or more hardware components to connect each of a plurality of second communication channels 112a, b, c to one or more corresponding internal strands 108.

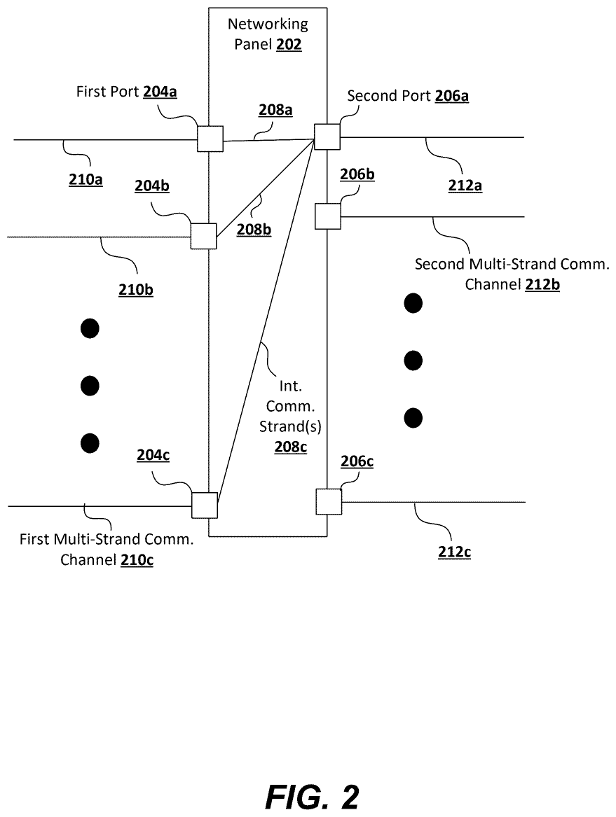

In some instances, a second port 106 can have one or more properties that are the same as or different from a corresponding first port 104. For example, in some instances, a second port 106 can be configured to receive a connector type (e.g., single-strand connector, multi-strand connector, etc.) that is the same as or different from a connector type associated with the first port 104. For example, in some instances, a second port 106 can include a port configured to receive a multi-strand connector having a first number of strands that is the same as or different from a second number of strands of a multi-strand connector associated with a corresponding first port 104. As a non-limiting illustrative example, in an example implementation, a first port 104 can be configured to receive an MPO-24 connector, and a second port 106 can include a port configured to receive a connector associated with an 800 Gb/s communication channel. In some instances, a second port 106 can be connected to a plurality of first ports 104 via a plurality of internal communication strands 108; or connected to just one first port 104 via one communication strand or a plurality of internal communication strands 108. Further details of an example networking panel in which at least one second port 106 is connected to a plurality of first ports 104 are provided below with respect to FIG. 2.

The internal communication strands 108a, 108b, 108c can be or include one or more transmission media for propagating signals within the networking panel 102. In some instances, the internal communication strands 108a, b, c can include one or more optical communication channels (e.g., fiber optic strands, etc.) configured to transmit data via light pulses, or another communication channel type (e.g., electrically conductive communication channels for transmitting electrical signals, etc.). In some instances, a plurality of internal communication strands 108a, b, c can be arranged to collectively “break out” a first multi-strand communication channel 110, such that a plurality of signals provided over a plurality of respective strands of the first multi-strand communication channel 110 are provided to a plurality of corresponding second ports 106a, b, c.

In some instances, a length of the internal strands can be adjusted to control a communication latency of each strand of the networking panel 102. For example, in some instances, a plurality of internal strands 108 can include a plurality of strands having a uniform or nearly uniform length, which can provide improved consistency in communication timing compared to some alternative implementations. In some instances, a plurality of internal strands 108 having nearly uniform length can include a plurality of strands wherein a length of a longest strand of the plurality of strands is within 30 percent of a mean length of the plurality of strands, such as within 20 percent, such as within 10 percent.

In some instances, a mapping of the internal communication strands 108a, b, c can be designed to reduce the impact of component failures compared to some alternative implementations. For example, in some instances, communication channels from a given compute node or other device, or rack of compute nodes or other group of devices, can be mapped across multiple separate communication channels 112 (e.g., multi-strand communication channels, etc.) such that a failure of a single communication channel, port 104, 106, or a single destination device or component (e.g., switch port of an active optical switch, etc.), does not result in a total loss of connectivity for a computing rack.

In some instances, an arrangement of the internal strands 108 (e.g., a prefabricated arrangement of internal strands 108 of a prefabricated networking panel 102, etc.) can include a predetermined arrangement configured to implement a data center wiring layout, such as a predetermined arrangement configured to implement the wiring layout using a reduced number of cables compared to some alternative implementations. For example, in some instances, an arrangement of internal strands 108 can include a predetermined arrangement configured to receive only one multi-strand communication channel 110 from each of a plurality of racks of compute nodes, and to route a plurality of signals of the single multi-strand communication channel 110 to a plurality of second ports 106 connected to a plurality of routing destinations (e.g., connected to a plurality of destinations via one or multiple communication channels per destination, etc.). Further details of an example multi-rack communication system comprising one or more networking panels are provided below with respect to FIG. 4.

In some instances, a plurality of internal strands 108 can include a plurality of communication strands having a similar (e.g., same) type (e.g., fiber optic strands, etc.) or different types. In some instances, a plurality of internal strands 108 can include a plurality of strands configured to transmit similar (e.g., same) or different types of data (e.g., according to similar or different communication protocols, etc.). As a non-limiting illustrative example, in some instances, each strand of a plurality of internal strands 108 can be configured to transmit one of a plurality of different types of data directed to a plurality of different destination types, such as management data, input/output data, interprocessor communication data, or the like. Further details of some example computing systems that may provide one or more different types of data to one or more types of routing destination are provided below with respect to FIG. 3.

The multi-strand communication channel 110 can be or include one or more transmission media for conveying signals between various networking components. In some instances, the multi-strand communication channel 110 can include a high-capacity transmission link, such as a multi-fiber optical cable or another aggregated communication assembly. The multi-strand communication channel 110 can be configured to facilitate parallel data transmission by utilizing a plurality of individual strands (e.g., optical fiber cores) bundled within a single protective sheath or jacket. For example, the multi-strand communication channel 110 can include a specific number of strands, such as 8, 12, 24, or 32 strands, to support varying levels of data throughput and connectivity requirements.

The multi-strand communication channel 110 can support various bandwidths and communication protocols. In some implementations, the multi-strand communication channel 110 can be characterized by high-speed data rates, such as 100 Gb/s, 400 Gb/s, 800 Gb/s, or another speed. The multi-strand communication channel 110 can be terminated with one or more multi-strand connectors, such as multi-fiber push-on (MPO) or multi-fiber termination push-on (MTP) connectors, which can be configured to interface with the first ports 104 of the networking panel 102. In some instances, a multi-strand connector can allow for the simultaneous connection of all strands within the channel to the networking panel 102 in a single mechanical action, thereby reducing installation complexity or maintenance complexity compared to individual strand connections.

In some instances, a plurality of strands of a multi-strand communication channel 110 can include a plurality of communication strands having a similar (e.g., same) type (e.g., fiber optic strands, etc.) or different types. In some instances, a plurality of strands of a multi-strand communication channel 110 can include a plurality of strands configured to transmit similar (e.g., same) or different types of data (e.g., according to similar or different communication protocols, etc.). As a non-limiting illustrative example, in some instances, a single multi-strand communication channel 110 connected to a rack of compute nodes can be configured to transmit a plurality of different types of data directed to a plurality of different destination types, such as management data, input/output data, interprocessor communication data, or the like. Further details of some example computing systems that may provide one or more different types of data to one or more types of routing destination are provided below with respect to FIG. 3.

A second communication channel 112a, b, c can be or include one or more transmission media for carrying communication signals between the networking panel 102 and various destinations. In some instances, a second communication channel 112a, b, c can include one or more optical fibers or other signal-carrying conduits. In some instances, a second communication channel 112a, b, c can include a type of communication channel type that is similar to (e.g., same as, etc.) or different from a type of a first multi-strand communication channel 110, such as a communication channel 112 that shares or does not share any property described herein with respect to a first multi-strand communication channel 110. For example, in some instances, a second communication channel 112 can include an eight-strand fiber optic channel configured to transmit signals at 800 Gb/s, or another communication channel type (e.g., 16-strand, 24-strand, 100 Gb/s, 400 Gb/s, etc.). In some instances, a second communication channel 112a, b, c can be terminated with one or more connector types, such as LC connectors, SC connectors, multi-fiber push-on (MPO) connectors, multi-fiber termination push-on (MTP) connectors, or very small form factor (VSFF) connectors. In some instances, a single networking panel 102 can be configured to interface (e.g., via a plurality of second ports 106) with a plurality of second communication channels 112a, b, c that utilize similar (e.g., same) or different connector types, such as similar or different communication channel 112 types directed to different routing destinations (e.g., data network communication channels, management network communication channels, backend network communication channels, etc.).

FIG. 2 is a block diagram of an example networking panel according to example implementations of aspects of the present disclosure. A networking panel 202 can include a plurality of first ports 204a, b, c each configured to receive a multi-strand connector of a first multi-strand communication channel 210a, b, c. The networking panel 202 can further include a plurality of second ports 206a, b, c each configured to receive one or more second multi-strand communication channels 212a, b, c. The networking panel 202 can further include a plurality of internal communication strands 208a, 208b, 208c connecting a second port 206a to a plurality of first ports 204a, b, c. For example, in some instances, the networking panel 202 can include a plurality of internal communication strands 208 in a breakout-breakin configuration, such that each of a plurality of first ports 204a, b, c is connected to a plurality of corresponding second ports 206a, b, c and such that one or more of the second ports 206a, b, c is connected to a plurality of corresponding first ports 204a, b, c via the internal communication strands 208.

In some instances, a networking panel 202, first port 204, second port 206, internal communication strand 208, first multi-strand communication channel 210, or second multi-strand communication channel 212 can be, comprise, be comprised by, or otherwise share one or more properties with a networking panel 102, first port 104, second port 106, internal communication strand 108, first multi-strand communication channel 110, or second communication channel 112, respectively. For example, in some instances, a networking panel 202, first port 204, second port 206, internal communication strand 208, first multi-strand communication channel 210, or second multi-strand communication channel 212 can have any property described herein with respect to a networking panel 102, first port 104, second port 106, internal communication strand 108, first multi-strand communication channel 110, or second communication channel 112, respectively, and vice versa. In some instances, a second multi-strand communication channel 212 can include a communication channel having a plurality of communication strands (e.g., fiber optic cores, etc.), such as a communication channel having any property described herein with respect to a first multi-strand communication channel 110 or second communication channel 112.

In some implementations, some or all of the first ports 204 of a networking panel 202 can each be connected to a plurality of corresponding second ports 206 (e.g., as described above with respect to FIG. 1 and a first port 104, etc.). In some instances, some or all of the second ports 206 can each be connected to a plurality of corresponding first ports 204. For example, in some instances, a networking panel 202 can include a networking panel 202 in which all of a plurality of first ports 204 are each connected to a plurality of corresponding second ports 206; some of a plurality of second ports 206 are each connected to a plurality of corresponding first ports 204; and some of the plurality of second ports 206 are each connected to just one corresponding first port 204. As a non-limiting illustrative example, in an example multi-rack data center with nine compute nodes per rack, a first multi-strand communication channel 210 may include nine or more communication strands (e.g., nine data network communication strands, etc.) respectively connected to the nine compute nodes, and a networking panel 202 may comprise eight internal communication strands 208 mapping eight of the nine communication strands to one second port 206a, and a ninth internal communication strand 208 mapping the ninth communication strand to a different second port 206b. In some instances, the different second port 206b can be configured to receive one communication strand from each of eight different compute racks; one communication strand from a first rack and seven from a second rack; or another configuration. Other examples are possible (e.g., many-to-many examples where all second ports 206 are coupled to multiple first ports 204; examples in which few or no second ports 206 are coupled to more than one first port 204; etc.).

FIG. 3 is a block diagram of an example system comprising one or more networking panels according to example implementations of aspects of the present disclosure. A computing system can comprise one or more compute nodes 314 coupled to one or more networking panels 302 via one or more first communication channels 310. The networking panels 302 can be coupled to one or more routing destinations 316 via one or more second communication channels 312, such that the compute node(s) 314 are coupled to the routing destination(s) 316 via the networking panel(s).

In some instances, a networking panel 302, first communication channel 310, or second communication channel 312 can be, comprise, be comprised by, or otherwise share one or more properties with a networking panel 102, 202, first communication channel 110, 210, or second communication channel 112, 212, respectively. For example, in some instances, a networking panel 302, first communication channel 310, or second communication channel 312 can have any property described herein with respect to a networking panel 102, 202, first communication channel 110, 210, or second communication channel 112, 212, respectively, and vice versa.

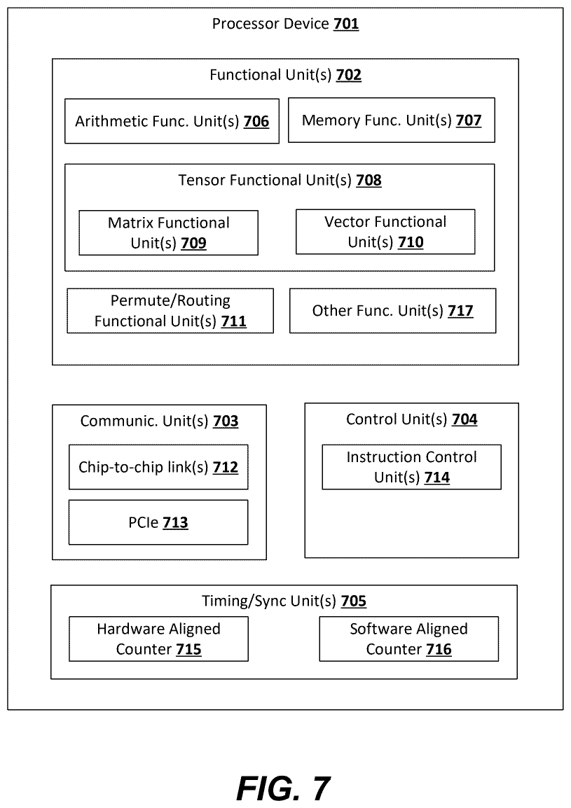

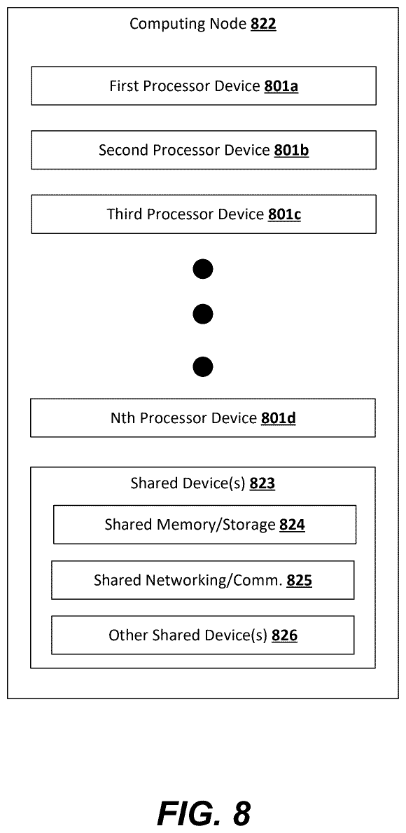

A compute node 314 can be or include one or more software, firmware, or hardware components for executing one or more computing operations, such as machine learning operations (e.g., machine learning inference operations, etc.) or other operations. In some instances, a compute node 314 can include a computing device, a processing resource, or an electronic host configured to process data and communicate over a network. In some implementations, a compute node 314 can include hardware acceleration components, such as one or more graphics processing units (GPUs), field programmable gate arrays (FPGAs), application-specific integrated circuits (ASICs), or other processor devices (e.g., central processing units (CPUs), etc.). In some instances, an ASIC can include an ASIC configured for machine learning operations, such as machine learning inference operations. In some instances, an ASIC can include an ASIC configured for tensor processing operations, such as tensor multiplication operations or activation function operations. As a non-limiting illustrative example, an ASIC configured for machine learning or tensor processing operations can include a language processing unit (LPU) or other ASIC type. In some instances, components of a compute node 314 can include processors, storage, memory, communication components, or other component types. Further details of an example processor device according to some aspects of the present disclosure are provided below with respect to FIG. 7 and processor 701. Further details of an example compute node are provided below with respect to FIG. 8.

In some instances, a compute node 314 can be configured for deployment within a modular housing system, such as a server rack or equipment enclosure. In some instances, a plurality of compute nodes 314 can be arranged in one or more racks, such as nine compute nodes per rack or the like.

In some implementations, a compute node 314 can function as a source or destination for various types of network traffic, including primary data traffic, backend processing traffic, or management and console traffic. In some instances, a compute node 314 can operate as a source or destination of data received from or directed to a plurality of routing destinations 316, such as a management device configured to send or receive management data for controlling or monitoring one or more aspects of one or more operations performed by a compute node 314; a data network device configured to provide data to or receive data from a compute node 314; other compute nodes 314 configured to send or receive backend data to or from another compute node 314; or the like. The networking panel 302 can be configured to manage a plurality of traffic types by routing or aggregating the communication strands associated with each compute node 314 via a plurality of internal communication strands 108.

A routing destination 316 can include various kinds of routing destinations, such as control nodes, compute nodes, data sources, routing devices, or other routing destinations. For example, in some instances, a routing destination 316 can include a routing device (e.g., patch panel, active optical switch, router, hub, etc.) configured to receive one or more signals from a network panel 302 via one or more communication channels, and to route the signal(s) to one or more other routing destinations 316 (e.g., control nodes, compute nodes, routing devices, etc.). Further details of an example system comprising a network panel coupled to another routing device are provided below with respect to FIG. 4.

In some instances, a network panel 302 can be configured to route a plurality of communication strands from a compute node 314 to a plurality of routing destinations 316, such as a plurality of different devices (e.g., control nodes, compute nodes, data sources, etc.) or a plurality of different ports of a single device (e.g., single routing device such as active optical switch, etc.). As a non-limiting illustrative example, in some instances, a networking panel 302 can receive, via a single multi-strand communication channel 310, a plurality of different communication strand types associated with a compute node 314 (e.g., communication strands coupled directly to the compute node 314; communication strands associated with a rack comprising the compute node 314; etc.); and route the plurality of different strand types to a plurality of distinct routing destinations 316 (e.g., different final routing destinations; different ports of a routing device; etc.). As a non-limiting illustrative example, in some instances, a multi-strand communication channel 310 can include two or more of: one or more data network lines, such as a data network line for each compute node 314 of a rack of compute nodes 314; one or more backend network lines, such as a backend network line for each compute node 314 of a rack of compute nodes 314; one or more management network lines, such as a single management network line for managing a rack of compute nodes 314; or other communication strands. Continuing the non-limiting illustrative example, the networking panel 302 can perform two or more of: routing the data network lines to a routing destination 316 for handling data network lines (e.g., active switch port configured to route data network lines, etc.); routing backend network lines to a routing destination 316 for handling backend network lines; routing management network lines to a management device; or other routing operations.

In some instances, a compute node 314 or routing destination 316 can be located close to or far away from a networking panel 302, such as in a rack that is the same as or different from a rack holding the networking panel 302. As a non-limiting illustrative example, in some instances, a networking panel 302 can be disposed in a networking rack (e.g., end-of-row networking rack, etc.) comprising a plurality of networking devices (e.g., switches, networking panels 302, etc.), and a plurality of compute nodes 314 can be disposed in compute racks that may be separate from the networking rack. Continuing the non-limiting illustrative example, in some instances, a routing destination 316 can include a networking device (e.g., active optical switch, etc.) located in the networking rack, or another routing destination 316 (e.g., management node located in another rack, compute node 314 located in another rack, etc.). Further details of an example multi-rack computing system comprising one or more networking racks are provided below with respect to FIG. 4.

FIG. 4 is a block diagram of a portion of an example multi-rack computing system according to example implementations of aspects of the present disclosure. A multi-rack computing system can include a plurality of compute racks 418a, b, c and one or more networking racks 420. The networking rack 420 can include one or more networking panels 402 each coupled to a plurality of compute racks 418a, b, c via a plurality of multi-strand communication channels 410 (e.g., via just one multi-strand communication channel 410 per compute rack 418, etc.). In some instances, the networking panel(s) 402 can be coupled to one or more active switches 422 or other devices 424 via one or more second communication channels 412. In some instances, some or all of the multi-strand communication channels 410 can each be operatively coupled (e.g., via breakout connector, networking panel, etc.) to a plurality of compute nodes 414a, b, c of a compute rack 418a, b, c, thereby providing dense connectivity between each compute rack 418 and the networking rack 420 with a reduced quantity of cabling (e.g., reduced number of communication channels, reduced total length of cabling used, etc.) compared to some alternative implementations.

In some instances, a networking panel 402, multi-strand communication channel 410, second communication channel 412, or compute node 414 can be, comprise, be comprised by, or otherwise share one or more properties with a networking panel 102, 202, 302, multi-strand communication channel 110, 210, 310, second communication channel 112, 212, 312, or compute node 314, respectively. For example, in some instances, a networking panel 402, multi-strand communication channel 410, second communication channel 412, or compute node 414 can have any property described herein with respect to a networking panel 102, 202, 302, multi-strand communication channel 110, 210, 310, second communication channel 112, 212, 312, or compute node 314, respectively, and vice versa.

In some instances, each multi-strand communication channel 410 can be coupled to a plurality of compute nodes 414a, b, c, such as a plurality of compute nodes 414a, b, c housed in the same compute rack 418 or different compute racks 418. In some instances, a compute node 414a, b, c can be coupled to one communication strand (e.g., fiber optic core, etc.) or multiple communication strands of a multi-strand communication channel 410. For example, in some instances, one or more compute nodes 414a, b, c may be coupled to two or more of: a first communication strand configured to send and receive management data, such as a first communication strand coupled to one or more management devices via a management network; one or more second strands configured to send and receive primary data (e.g., input data to be processed by a compute node 414, etc.) via a data network; one or more third communication strands coupled to a backend network, such as a backend network configured to provide chip-to-chip communication (e.g., deterministic-timing chip-to-chip communication between deterministic-timing processor devices, etc.) of intermediate values computed by one or more compute nodes during a parallel computing operation; or other communication strand types configured to carry other types of data or coupled to other devices or networks via a networking panel 402. Similarly, in some instances, a multi-strand communication channel 410 can carry data associated with one type of interface or a plurality of interface types (e.g., GPU interface, language processing unit (LPU) interface, compute interface, etc.), a plurality of client types (e.g., server, LPU, GPU, etc.), or the like. In some instances, a plurality of compute nodes 414 of a compute rack 418 can include one type of compute node (e.g., a plurality of LPU-based compute nodes, etc.) or a plurality of compute node types.

As a non-limiting illustrative example, in some instances, a multi-strand communication channel 410a can include a 24-strand fiber optic cable, a compute rack 418a can hold nine compute nodes, and each of the nine compute nodes can be coupled to at least one strand associated with a data network and at least one strand coupled to a backend network. Continuing the non-limiting illustrative example, at least one of the nine compute nodes 414 of the compute rack 418a can be coupled to at least one strand coupled to a management network, and the compute node 414 coupled to the management network can propagate management network signals to and from other compute nodes 414 of the rack (e.g., via within-rack chip-to-chip communication channels not expressly depicted in FIG. 4, etc.), such that 19 of 24 strands of the example multi-strand communication channel 410a can be used to provide data network communication, backend network communication, and management network communication to a plurality of compute nodes 414 of a given rack 418a.

In some instances, a multi-strand communication channel 410 can be coupled to a one or more communication ports of each of a plurality of compute nodes 414a of a compute rack 418 in various ways, such as via a breakout connector (e.g., cassette-style breakout connector, fanout connector, etc.) or other device (e.g., top-of-rack breakout panel such as top-of-rack breakout panel having or not having one or more properties described herein with respect to FIG. 1 and a networking panel 102, etc.).

A compute rack 418 or networking rack 420 can be or include one or more structures (e.g., compute rack, server rack, equipment enclosure, etc.) for housing, supporting, and interconnecting computing resources. In some instances, a compute rack 418 or networking rack 420 can include various sizes or rack types, such as a 19-inch or 21-inch rack characterized by a vertical height measured in rack units (e.g., 20RU, 42RU, 48RU, 52RU, etc.), or another rack size.

In some instances, a compute rack 418 can hold a plurality of compute nodes 414 and zero or more other components, such as networking components, control devices, or other components.

In some instances, a networking rack 420 can hold one or more networking panels 402 (e.g., a plurality of networking panels 402, etc.); one or more active switches 422; and zero or more other devices 424, such as networking devices (e.g., routing devices, patch panels, etc.), control devices, or other devices.

In some instances, a computing system (e.g., data center, etc.) can include a plurality of compute racks 418 for each networking rack 420. In some instances, a number of compute racks 418 of a computing system can be greater than 20 times a number of networking racks 420 of the computing system, such as greater than 50 times the number of networking racks 420, such as greater than or equal to 100 times the number of networking racks 420. For example, in some instances, a networking rack 420 can include a group of one or more networking panels 402 collectively configured to receive more than 20 (e.g., more than 50, such as greater than or equal to 100, etc.) multi-strand communication channels 410 from more than 20 (e.g., more than 50, such as greater than or equal to 100, etc.) compute racks 418, and to route communications from each respective strand of the more than 20 multi-strand communication channels 410 to an appropriate routing destination, such as an appropriate port of an active switch 422 of the networking rack 420. In some instances, a networking rack 420 can be coupled to a plurality of multi-strand communication channels 410 collectively having greater than 500 communication strands (e.g., fiber optic cores, etc.), such as greater than 1000, such as greater than or equal to 2000.

As a non-limiting illustrative example, an example computing system according to some aspects of the present disclosure can include one or more groups of more than 100 compute racks 418 (e.g., between 100 and 300 compute racks 418, etc.) collectively coupled to two or fewer networking racks 420, with each networking rack 420 being coupled to a plurality of compute racks 418 via a set of multi-strand communication channels 410 having a total of between 2000 and 5000 fiber optic cores. In the non-limiting illustrative example computing system, each of a plurality of compute racks 418 can be coupled to exactly one networking rack 420 via exactly one multi-strand communication channel 410, thereby greatly reducing a number of communication cables required to wire a multi-rack computing system compared to some alternative implementations (e.g., implementations with separate cables for each compute node; implementations with separate cables for each type of network traffic, such as data network traffic, backend network traffic, and management network traffic, etc.). However, this is not required, and other implementations are possible without deviating from the scope of the present disclosure.

An active switch 422 can be or include one or more software, firmware, or hardware components for managing, routing, and processing communication signals within a computing system. In some instances, an active switch 422 can include an optical switch configured to provide switching for optical signals. In some instances, an active switch 422 can include an Ethernet switch configured to provide switching for communications transmitted according to an Ethernet protocol. In some instances, an active switch 422 can include a plurality of ports coupled to a plurality of communication channels 412 (e.g., communication channels 412 coupled to a networking panel 402; communication channels 412 coupled to another device, such as a device associated with a management network, data network, or backend network of a multi-rack computing system, etc.), and can be configured to selectively (e.g., responsive to one or more control signals, etc.) couple pairs of ports to provide communication between pairs of communication channels 412. In some instances, each port of an active switch 422 or communication channel 412 coupled to the active switch 422 can have various capacities or bandwidths, such as an 800 Gb/s or another value. In some instances, a computing system can include a plurality of active switches 422 implementing various network topologies, such as a spine-leaf topology or another topology. In some instances, a computing system can include a one or more active switches 422 (e.g., plurality of active switches 422 disposed in the same or different networking racks 420, etc.) implementing a plurality of separate networks, such as one or more of a management network, a data network, a backend network, or one or more other network types.

In some instances, a computing system according to some aspects of the present disclosure can be configured to add, drop, or otherwise reconfigure one or more individual communication strands (e.g., fiber cores, etc.) of one or more multi-strand communication channels 410 without necessarily performing any recabling operations (e.g., without connecting or disconnecting any new cables from a rack 418, 420, panel 402, switch 422, or the like, etc.). For example, in some instances, a computing system can perform a first set of operations using a strict subset of a plurality of strands of each multi-strand communication channel 410, such that one or more strands of each multi-strand communication channel 410 are unused during the first set of operations; and perform a second set of operations using at least one of the unused strands (e.g., responsive to equipment failure; responsive to a change in computing system architecture; etc.). In some instances, a computing system can be configured to add, drop, or otherwise reconfigure one or more strands of a multi-strand communication channel 410 using an active switch 422, without necessarily performing any rewiring operations. For example, a first set of strands of a given multistrand communication channel 410a can be coupled to a first port of the active switch 422; a second set of strands of the multi-strand communication channel 410a can be coupled to a second port of the active switch 422; and the active switch 422 can add, drop, or otherwise reconfigure the second set of strands by connecting, disconnecting, or otherwise reconfiguring the second port within a network topology implemented by the active switch 422. In this manner, for instance, a computing system can add or drop a subset of communication strands (e.g., fiber optic cores, etc.) within a given multistrand communication channel 410 without rewiring (e.g., connecting or disconnecting, splicing, etc.) the multi-strand communication channel 410 itself, and without necessarily affecting the operation of other communication strands within the same multistrand communication channel 410 (e.g., within the same jacket, etc.).

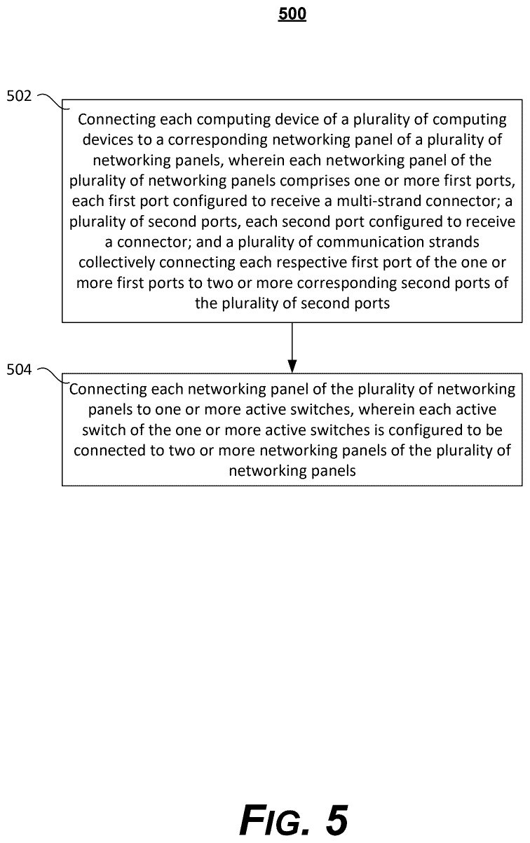

FIG. 5 depicts a flowchart diagram of an example method for wiring a data center according to example embodiments of the present disclosure. Although FIG. 5 depicts steps performed in a particular order for purposes of illustration and discussion, the methods of the present disclosure are not limited to the particularly illustrated order or arrangement. The various steps of example method 500 can be omitted, rearranged, combined, and/or adapted in various ways without deviating from the scope of the present disclosure.

At 502, example method 500 can include connecting each computing device of a plurality of computing devices to a corresponding networking panel of a plurality of networking panels, wherein each networking panel of the plurality of networking panels comprises one or more first ports, each first port configured to receive a multi-strand connector; a plurality of second ports, each second port configured to receive a connector; and a plurality of communication strands collectively connecting each respective first port of the one or more first ports to two or more corresponding second ports of the plurality of second ports. In some instances, example method 500 at 502 can include using one or more systems or performing one or more activities described with respect to FIGS. 1-4.

At 504, example method 500 can include connecting each networking panel of the plurality of networking panels to one or more active switches, wherein each active switch of the one or more active switches is configured to be connected to two or more networking panels of the plurality of networking panels. In some instances, example method 500 at 504 can include using one or more systems or performing one or more activities described with respect to FIGS. 1-4.

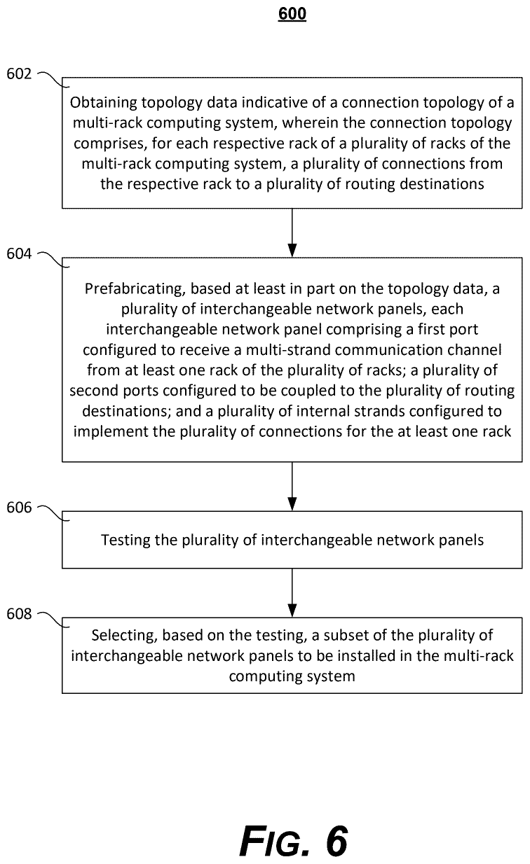

FIG. 6 depicts a flowchart diagram of an example method for fabricating and using a plurality of network panels according to example embodiments of the present disclosure. Although FIG. 6 depicts steps performed in a particular order for purposes of illustration and discussion, the methods of the present disclosure are not limited to the particularly illustrated order or arrangement. The various steps of example method 600 can be omitted, rearranged, combined, and/or adapted in various ways without deviating from the scope of the present disclosure.

At 602, example method 600 can include obtaining topology data indicative of a connection topology of a multi-rack computing system, wherein the connection topology comprises, for each respective rack of a plurality of racks of the multi-rack computing system, a plurality of connections from the respective rack to a plurality of routing destinations. In some instances, example method 600 at 602 can include using one or more systems or performing one or more activities described with respect to FIGS. 1-4.

At 604, example method 600 can include prefabricating, based at least in part on the topology data, a plurality of interchangeable network panels, each interchangeable network panel comprising a first port configured to receive a multi-strand communication channel from at least one rack of the plurality of racks; a plurality of second ports configured to be coupled to the plurality of routing destinations; and a plurality of internal strands configured to implement the plurality of connections for the at least one rack. In some instances, a plurality of interchangeable network panels can be mass-produced at a manufacturing facility, thereby reducing a cost of fabricating the plurality of network panels compared to some alternative implementations (e.g., implementations involving manual splicing of multi-strand fiber optic cables, etc.). In some instances, example method 600 at 604 can include using one or more systems or performing one or more activities described with respect to FIGS. 1-4.

At 606, example method 600 can include testing the plurality of interchangeable network panels. In some instances, testing can be performed at a fabrication facility prior to deployment in a data center, thereby reducing a cost of testing compared to some alternative implementations. In some instances, example method 600 at 606 can include using one or more systems or performing one or more activities described with respect to FIGS. 1-4.

At 608, example method 600 can include selecting, based on the testing, a subset of the plurality of interchangeable network panels to be installed in the multi-rack computing system. In some instances, example method 600 at 608 can include using one or more systems or performing one or more activities described with respect to FIGS. 1-4.

FIG. 7 is a block diagram of an example processor device 701 according to example implementations of aspects of the present disclosure. The processor device 701 can include one or more functional units 702; one or more communication units 703; one or more control units 704 (e.g., instruction control unit(s) 714, etc.); one or more timing or synchronization units 705; or other components. In some instances, functional unit(s) 702 of the processor device 701 can include one or more of: arithmetic functional unit(s) 706; memory functional unit(s) 707; tensor functional unit(s) 708 (e.g., matrix functional unit(s) 709, vector functional unit(s) 710, etc.), permute or routing functional units 711, or other functional units 717. Communication unit(s) 703 can include, for example, one or more of chip-to-chip communication link(s) 712, peripheral component interconnect express 713 components, or other communication unit(s) 703. Timing and synchronization units 705 can include, for example, one or more hardware-aligned counters 715, one or more software-aligned counters 716, or other timing or synchronization components.

A processor device 701 can include various types of processor architectures. In some instances, a processor device 701 can include a single-core or multi-core processor device 701. In some instances, a processor device 701 can include an integrated circuit located on a single die or a processor device 701 distributed over multiple dies connected together (e.g., directly connected such as via face-to-face connection, indirectly connected such as via one or more interposers, etc.). In some instances, a processor device 701 can include one or more of: one or more field-programmable gate arrays (FPGAs); one or more application-specific integrated circuits (ASICs), such as ASICs for machine-learning inference, matrix multiplication, floating-point operations, or the like; one or more graphics processor units (GPUs); one or more tensor processing devices; or other processor type. In some instances, a processor device 701 can include a deterministic processor device or a non-deterministic processor device (e.g., processor device configured to operate according to a deterministic or non-deterministic timing, etc.). In some instances, a processor device 701 can include a processor device having a plurality of dedicated special-purpose functional units, or a processor device having one or more general-purpose functional units (e.g., multi-core processor having a plurality of general-purpose processor cores, etc.). For example, in some instances, a processor device 701 can include a single-core processor device 701 having a plurality of special-purpose functional units 702 having distinct functions, such as functional units 702 having distinct instruction set architectures.

In some instances, a processor device 701 can include a deterministic processor device. A deterministic processor device can include, for example, a processor device configured to perform a plurality of operations according to a predetermined order, such as a predetermined program order defined by a compiler. In some instances, a deterministic processor device can include a processor device configured to perform a plurality of operations according to a predetermined timing or according to a predetermined temporal relationship between operations. For example, in some instances, a deterministic processor can include a processor configured to receive one or more computer-executable instructions (e.g., compiled instructions, etc.) comprising timing data; and execute the instruction(s) according to a predetermined time or predetermined temporal relationship indicated by the timing data. Timing data can include, for example, one or more of: data indicative of a clock cycle on which to execute a particular operation; data indicative of a temporal relationship between one or more first operations and one or more second operations, such as data indicative of a number of clock cycles to pause after a first operation (e.g., data transfer operation, instruction transfer operation, floating-point operation, etc.) is completed before performing a second operation (e.g., floating-point operation, tensor processing operation, etc.); data indicative of one or more operations or instructions configured to have an effect on a timing of operations, such as data indicative of one or more no-operation (NOP) operations or sleep operations, such as a repeated-NOP instruction to cause a functional unit 702 or other component of a processor device 701 to remain idle for a predetermined number of clock cycles; or other timing data.

In some instances, a deterministic processor device can include a processor device configured to receive, from a compiler, a set of computer-executable instructions controlling a timing of a plurality of operations associated with the computer-executable instructions; and perform the plurality of operations according to the timing. For example, in some instances, a deterministic processor device can include a processor device configured to receive a compiled program configured to cause, for each respective operation of a plurality of operations (e.g., arithmetic operations such as floating-point operations, tensor operations, etc.) to be performed on one or more respective data operands (e.g., numerical operands such as machine-learning model parameters, activation values, etc.), an instruction associated with the respective operation to intersect with the respective data operand at a predetermined time instant (e.g., clock cycle, clock cycle offset relative to an initial clock cycle, etc.) defined in the compiled program. In some instances, a deterministic processor can include a processor device having one or more components (e.g., functional unit(s) 702, communication unit(s) 703, etc.) having an instruction set architecture comprising instructions to control a timing of one or more operations of the one or more components.

In some instances, a deterministic processor device 701 can include a processor device configured to route data between functional units 702 of the processor device 701 according to a predetermined timing, predetermined routing or pathing, or both. For example, in some instances, a deterministic processor device 701 can include a processor device configured to receive compiled instructions comprising data indicative of one or more data transfers operations to be performed according to one or more predetermined routes determined by a compiler, according to one or more predetermined timing values defined by the compiler, or both. In this manner, for instance, a deterministic processor device 701 can enable a compiler to perform compile-time load balancing for a plurality of data paths, and can execute a plurality of runtime data transfers according to the compile-time load balancing.

In some instances, a deterministic processor device 701 can include a processor that lacks one or more non-deterministic components that may be commonplace among non-deterministic processor devices, such as branch prediction units, tiered or hierarchical cache devices, runtime load balancing, or other sources of runtime non-determinism (e.g., non-deterministic timing of operations, non-deterministic choice of operations such as non-deterministic routing of data, etc.). For example, in some instances, a processor device 701 can lack any branch prediction components, and can be configured to execute every operation of a compiled program according to a predetermined program order. As another example, in some instances, one or more memory functional units 707 can lack a cache hierarchy or lack any non-deterministic memory component(s). For example, in some instances, one or more memory functional units 707 can be configured to operate deterministically, such as according to a predetermined timing defined by a compiler. For example, in some instances, one or more memory functional units 707 can be configured to perform one or more read operations at one or more times predetermined by a compiler; perform one or more write operations at one or more times predetermined by the compiler; perform one or more refresh operations at one or more times predetermined by the compiler, such that the compiler can have explicit control over a refresh timing of the memory functional unit(s) 707; or the like. For example, in some instances, the compiler can compile a program or other executable into a set of deterministic operations that can be executed by the functional unit(s) 702 at known times specified by a deterministic schedule.

However, although a deterministic processor device 701 can lack some common sources of non-determinism, in some instances, a deterministic processor device 701 can include or interact with one or more non-deterministic components or devices without deviating from the scope of the present disclosure. As a non-limiting illustrative example, in some instances, a deterministic processor device 701 can include a PCIe 713 component configured to perform external input/output (I/O) operations, which can in some instances include input/output operations having a non-deterministic timing (e.g., I/O operations using a non-deterministic PCIe 713 device; I/O operations receiving input from non-deterministic external device(s); etc.). In some instances, a deterministic processor device 701 can interact with non-deterministic component(s) or device(s) (e.g. components or devices internal or external to the processor, etc.), while maintaining deterministic operation of the remaining components of the processor device 701 by designating one or more predetermined time windows to interact with the non-deterministic component(s) in a deterministic manner. For example, in some instances, a processor device 701 can be configured to check, at each of a plurality of predetermined times, whether one or more inputs (e.g., inference request(s), etc.) have been received via a PCIe device 713; and, if the processor device 701 determines that an input has been received, to process the input (e.g., write the input to a designated memory location or region, etc.) according to a predetermined timing or predetermined set of instructions (e.g., according to a set of operations configured to fit within a predetermined time window reserved for non-deterministic external I/O operations, etc.).

In some instances, a processor device 701 can include a processor device configured for single-instruction multiple-data (SIMD) operation. For example, in some instances, a processor device 701 can be configured to receive one or more computer-executable instructions that are each indicative of an operation to be performed on a plurality of operands, such as a vector of numerical operands; a tensor of numerical operands; or the like. In some instances, a SIMD processor device can include a processor device configured to provide a single instruction to a plurality of functional units 702 (e.g., adjacent functional units 702 arranged in a functional region, etc.) to cause each respective functional unit 702 of the plurality of functional units 702 to execute the instruction on one or more distinct operands provided to the respective functional unit 702 (e.g., routed to the respective functional unit 702 according to a predetermined compiler-defined routing, etc.).

In some instances, a processor device 701 can include a single-core processor device, or a processor device configured to operate as a single-core device (e.g., flexible-operation processor device having two hemispheres that can be operated in series as a single-core device or in parallel as a multi-core device, etc.). For example, in some instances, a single-core processor device can include a processor device configured to receive a single set of instructions (e.g., compiled instructions, etc.) and to execute, in a serial or pipelined fashion using one or more functional units 702, a set of operations defined by the single set of instructions. For example, in some instances, a single-core processor device 701 can include a processor device configured to obtain (e.g., receive, retrieve, etc.) one or more instructions (e.g., SIMD instructions, etc.) indicative of a plurality of operations (e.g., plurality of SIMD operations, etc.) to be performed on one or more operands; and perform, in series using a plurality of functional units 702, the plurality of operations (e.g., SIMD operations wherein each operation is a multiple-data operation, etc.) on the one or more operands.

Functional unit(s) 702 can include, for example, one or more components (e.g., integrated circuit components, etc.) configured to perform operations on one or more operands (e.g., data operands, etc.). In some instances, functional unit(s) 702 can include deterministic functional units 702, such as deterministic functional units configured to perform one or more operations in a predetermined program order, according to a predetermined timing or temporal relationship, or the like. In some instances, a set of functional units 702 can include a plurality of dedicated or special-purpose functional units 702, such as distinct functional units 702 having distinct functions or sets of functions (e.g., limited or specialized function sets, etc.). In some instances, functional unit(s) 702 can include functional units configured to perform multiple operations per instruction for at least some instructions, such as single-instruction multiple-data (SIMD) functional unit(s) 702, and/or functional unit(s) 702 configured to process instruction(s) directed to multiple computing operations (e.g., multiple repetitions of a single type of operation, pipeline of multiple different operations, etc.).

In some instances, a set of dedicated functional unit(s) 702 can include distinct dedicated functional units 702 for each of a plurality of steps in a machine-learning inference pipeline, such as a distinct dedicated functional unit for each component of a category or type of machine-learning model layer (e.g., convolutional layer, attention layer, fully connected layer, etc.). For example, in some instances, a set of dedicated functional units 702 for implementing a fully connected layer of a machine-learning model can include one or more matrix functional units 709 for performing matrix multiplication between a parameter tensor (e.g., weight matrix, etc.) and a tensor (e.g., vector, etc.) of input values to the fully connected layer, and one or more vector functional units 710 for performing an activation function of the fully connected layer. As another example, in some instances, a set of dedicated functional units 702 for implementing a convolutional layer of a machine-learning model can include one or more permute/routing functional units 711 configured to perform one or more data reshaping operations corresponding to one or more convolutions (e.g., two-dimensional convolutions, one-dimensional convolutions, etc.); and one or more other functional units 702 (e.g., matrix functional unit(s) 709, vector functional unit(s) 710, etc.) for performing additional operations associated with a convolutional layer or convolutional neural network (e.g., matrix multiplication, pooling, activation functions, etc.).

In some instances, a plurality of dedicated functional units 702 can include a first functional unit 702 configured to perform a set of operations that is different (e.g., completely disjoint from or partially overlapping, etc.) from a second set of operations associated with a second functional unit 702. In some instances, a plurality of special-purpose or dedicated functional units 702 can have a plurality of distinct instruction set architectures, such as limited or special-purpose instruction set architectures each supporting a limited or special-purpose set of operations. As a non-limiting illustrative example, in some instances, a set of dedicated functional units 702 can include one or more of: a matrix functional unit 709 configured to perform a first set of matrix operations (e.g., matrix multiplication operations, etc.); a vector functional unit 710 configured to perform a set of vector operations different from the matrix operations (e.g., activation function operations such as rectified linear unit (ReLU), sigmoidal, softmax, or other activation function operations; normalization operations; etc.); a permute/routing functional unit 711 configured to perform one or more data routing, data permutation, or data reshaping functions (e.g., tensor permutation or reshaping, etc.) different from the matrix operation(s) and different from the vector operation(s); or other dedicated functional unit(s) 702. Other examples are possible.

In some instances, functional unit(s) 702 can include functional units organized into functional regions of a processor die, such as compact functional regions configured to facilitate low-latency propagation of instructions or operands within a functional unit 702 or between adjacent functional units 702. As a non-limiting illustrative example, in some instances, one or more functional units 702 can be organized into functional slices along a first axis of a processor die, thereby enabling low-latency propagation of one or more instructions along the axis, low-latency propagation of operand data along a second axis, or the like.

In some instances, functional unit(s) 702 or functional region(s) can be geographically organized on a processor die to reduce (e.g., minimize or nearly minimize; reduce relative to a random arrangement or relative to a conventional multi-core central processing unit or conventional graphics processing unit, etc.) a communication cost (e.g., latency cost, power cost, communication distance, etc.) associated with one or more computational pipelines, such as machine-learning inference pipelines. For example, in some instances, one or more functional units 702 or functional regions of a processor device 701 for performing a sequentially first operation in a computational pipeline can be geographically close to one or more functional units 702 for performing a sequentially second operation in the computational pipeline. Example computational pipelines can include, for example, inference pipelines associated with common machine-learning model, layer, or head architectures, such as convolutional architectures; attention architectures; fully connected layer architectures; selective structured state space machine architectures; gating architectures (e.g., long short-term memory, etc.); or another machine learning architecture.

In some instances, functional unit(s) 702 can include functional units configured to perform multiple operations per instruction for at least some instructions, such as single-instruction multiple-data (SIMD) functional unit(s) 702 or functional units 702 configured to operate without necessarily receiving explicit instructions for each operation. For example, functional unit(s) 702 configured to operate without necessarily receiving explicit instructions for each operation can include one or more of: functional unit(s) 702 configured to receive intermittent instructions and perform multiple operations per instruction (e.g., repeated single operation, pipeline of multiple different operations, etc.); functional unit(s) 702 configured to operate without instructions according to a default operation; or the like. In this manner, for instance, an amount of communication required to provide instructions to the functional units 702 can be reduced, and operation of the processor device 701 can in some instances be simplified compared to some alternative implementations.

For example, in some instances, a SIMD functional unit 702 can include a tensor functional unit 708 configured to execute an instruction on a plurality of numerical values, such as a vector or matrix of numerical values. For example, in some instances, a tensor functional unit 708 can be configured to receive an instruction; and process, according to the instruction, a tensor (e.g., one-dimensional vector tensor, two-dimensional matrix tensor, etc.) comprising a plurality of numerical values (e.g., dozens of numerical values per instruction, such as hundreds, such as 320 numerical values in some examples). In some instances, a tensor functional unit 708 can be configured to process some or all of a plurality of values simultaneously, or to execute a single-instruction multiple-data instruction according to a staggered timing.

As another example, in some instances, a functional unit 702 configured to operate based on intermittent instructions can include a functional unit 702 configured to repeat one or more operations, such as a functional unit 702 configured to continue performing a given operation (e.g., an operation associated with a most recently received instruction, etc.) periodically (e.g., at every clock cycle; at every Nth clock cycle; etc.) for some amount of time (e.g., indefinitely, for a finite period of time such as a time period defined by a previously received instruction, etc.) in the absence of explicit instructions. In some instances, a functional unit 702 can include a functional unit 702 configured to receive and execute one or more repetition instructions (e.g., having an instruction set architecture comprising one or more repetition instructions, etc.). A repetition instruction can include, for example, an instruction to cause the functional unit 702 to repeat (e.g., repeat at every clock cycle; at every Nth clock cycle, where N can be a parameter of the instruction; etc.) a previous instruction or set of instructions a number of times specified by the instruction; an instruction indicative of an operation to be repeated (e.g., arithmetic operation, matrix operation, vector operation, etc.), the instruction having a repetition parameter indicating a number of times to repeat the operation; or the like. In some instances, a repetition instruction can include one or more offset parameters, such as a time offset parameter (e.g., number of cycles to wait between repetitions, etc.), location offset parameter indicative of a distance between consecutive locations (e.g., functional unit 702 location, memory location, data path location, etc.) associated with a repeated operation, or other offset parameter.

As another example, in some instances, a functional unit 702 can include a functional unit 702 configured to receive a single instruction indicative of multiple distinct operations to be performed on a single operand or set of operands, such as a multiply-accumulate (MACC) instruction or matrix multiplication instruction indicative of one or more multiply operations and one or more accumulate operations to be performed on one or more outputs of the multiply operation(s). In some instances, a functional unit 702 can include a pipelined hardware architecture (e.g., systolic array pipelined hardware, deterministic streaming hardware, etc.) configured to provide (e.g., directly; indirectly via one or more buffers, registers, or other memory components; etc.) an output of one or more first hardware devices (e.g., floating-point units, etc.) for performing earlier (e.g., sequentially first, etc.) operations of a multi-operation instruction to an input of one or more second hardware devices for performing later (e.g., sequentially second or last, etc.) operations of the multi-operation instruction. In some instances, a pipelined hardware architecture of a functional unit 702 can include a geographically compact architecture, wherein a plurality of components for performing a multi-operation instruction can be adjacent or otherwise close together on a processor die.

An arithmetic functional unit 706 can include, for example, one or more functional units 702 for performing various arithmetic operations, such as floating-point operations, integer operations, or quantized operations; simple operations (e.g., add, multiply, format conversion, etc.) or complex/combined operations (e.g., multiply-accumulate, etc.); single-operand operations or multi-operand operations (e.g., tensor operations, etc.); or other arithmetic operations. In some instances, an arithmetic functional unit 706 can be a tensor functional unit 708 or component thereof, or have one or more properties described below with respect to tensor functional unit(s) 708.

A memory functional unit 707 can include, for example, one or more functional units 702 for reading, writing, or storing various kinds of data, such as operand data, instruction data, or other data. Data storage can include, for example, temporary storage of one-time-use or ephemeral values (e.g., computed operand values, etc.), longer-term storage of values to be reused (e.g., machine-learning model weights, compiled computer-executable instructions, etc.), or other storage. In some instances, a memory functional unit 707 can include one or more low-latency, high-bandwidth, or otherwise rapidly accessible memory devices, such as random access memory (RAM) devices (e.g., static random access memory (SRAM), high-bandwidth memory (HBM), dynamic random access memory (DRAM), etc.), registers, or other low-latency devices.

In some instances, one or more memory functional units 707 can be configured to share a global address space accessible to a plurality of functional units 702. For example, in some instances, a global address space can include all memory locations available to the processor device 701 (e.g., including any external memory modules, etc.), such that any functional unit 702 of the processor device 701 can obtain (e.g., receive at a predetermined time defined by the compiler, such as without requiring the functional unit 702 to output any request for the data obtained). In some instances, a set of memory functional unit(s) 707 can include, or a processor device 701 can have access to, one or more internal (e.g., on-chip) memory functional units 707; one or more external (e.g., off-chip, near-compute, etc.) memory units; or both.

A tensor processing unit 708 can include, for example, a functional unit 702 to perform one or more operations (e.g., arithmetic operations such as tensor multiplication, elementwise multiplication, normalization, activation function operations, etc.) on one or more tensors (e.g., matrices, vectors, etc.). In some instances, a tensor processing unit 708 can include a matrix functional unit 709; a vector functional unit 710; or another functional unit.

A matrix processing unit 709 can include, for example, a functional unit 702 configured to perform one or more operations on a matrix (e.g., two-dimensional matrix, flattened matrix, etc.) of operands (e.g., numerical values such as floating-point values, etc.). In some instances, a matrix processing unit 709 can include a functional unit 702 configured to perform matrix multiplication or other matrix operations.

A vector processing unit 710 can include, for example, a functional unit 702 configured to perform one or more operations on a vector (e.g., one-dimensional vector, flattened tensor, etc.) of operands (e.g., floating-point numerical values, etc.). In some instances, a vector processing unit 710 can include a functional unit 702 configured to perform one or more of: one or more activation function operations (e.g., sigmoidal or logistic activation function, linear unit activation function such as rectified linear unit (ReLU), softmax activation function, etc.), one or more normalization operations (e.g., L2 normalization, etc.), one or more combining operations (e.g., attention-based combining, etc.) to combine a set (e.g., pair, trio, etc.) of vectors, one or more constituent operations configured to be combined to support a class of related operations (e.g., class or category of normalization operations, class or category of activation function operations, etc.), or the like.

A permute/routing functional unit 711 can include, for example, a functional unit 702 configured to perform one or more data permuting or data routing operations. In some instances, a data permuting operation can include one or more swap or reordering operations configured to reorder data in an ordered format (e.g., vector format or other tensor format; ordered arrangement of registers, signal lines, or other hardware units; etc.), such as without changing a shape (e.g., length, width, number of dimensions, etc.) of the ordered format. Example reordering operations can include, for example, rotation or translation operations; arbitrary reordering operations defined by one or more reordering maps such as a gather map; or other reordering operations. In some instances, a data permuting operation can include a reshaping operation, such as a reshaping operation changing a number of dimensions of a data structure (e.g., tensor, hardware devices corresponding to a tensor, etc.), changing a size of one or more dimensions of the data structure, or the like. As a non-limiting illustrative example, in some instances, a reshaping operation can include a tensor flattening operation to convert a multi-dimensional tensor into a one-dimensional data structure (e.g., vector, hardware configuration corresponding to a vector, one-dimensional data stream corresponding to a vector, etc.). As another example, in some instances, a reshaping operation can include an expansion or duplication operation, such as a reshaping operation to generate an expanded convolutional kernel to implement a filter component of a convolutional neural network. In some instances, a routing operation can include a permuting operation to change an ordering of operands input to one or more fixed or predetermined data paths, or another routing operation (e.g., switching operation; pair of operations comprising a send and a receive; etc.). In some instances, a permuting operation can include a routing operation to change a routing of operands to hardware having a fixed or predetermined input order.

In some instances, a memory functional unit 707; a tensor, matrix, or vector functional unit 708, 709, 710; or a permute/routing functional unit 711 can be or include a deterministic functional unit 702 configured to execute instruction(s) at a predetermined time defined by a compiler; a single-instruction multiple-operation functional unit 702 configured to perform a plurality of operations based on one instruction; or have any other property described herein with respect to functional unit(s) 702.

Communication units 703 can include various components for performing communication operations (e.g., input, output, etc.) between the processor device 701 and other devices (e.g., processor devices, computing devices, external memory devices, etc.) or components, or within the processor device 701. In some instances, communication units 703 can include deterministic communication units (e.g., communication units performing operations according to a predetermined program order, timing, temporal relationship, or other predetermined property, etc.), non-deterministic communication units (e.g., communication units having non-deterministic timing properties, communication units configured to communicate with non-deterministic external devices, etc.), or both. For example, in some instances, a deterministic processor device 701 can include a plurality of deterministic chip-to-chip communication links 712 configured to communicate with other deterministic processor devices 701 (e.g., using deterministic communication operations having a predetermined timing, communication path, or other property), along with one or more PCIe components 713 configured to interact with one or more non-deterministic components. In some instances, communication units 703 can include or have access to various components, such as serializer-deserializer (SerDes) units configured to serialize data to be output or deserialize data received as input; communication ports, connections, interface units, or the like; communication lines (e.g., electrically conductive signal traces, electrically conductive wires, optical fibers, cables, etc.); routing or data permutation components (e.g., internal routing or permutation components such as switching components; external components coupled to the processor device 701 such as routers, repeaters, switches, panels, or the like); or other components configured to facilitate one or more communication operations.

Chip-to-chip communication units 712 can include, for example, any device or component for communicating with another processor device (e.g., processor device 701, etc.), such as one or more serializer-deserializer units, one or more communication channels (e.g., signal lines, etc.), one or more connection components (e.g., ports, pins, connection pads, etc.), or the like. In some instances, a processor 701 can include a plurality of chip-to-chip communication ports to facilitate direct communication with a plurality (e.g., four, eight, sixteen, etc.) of other chips, such as according to a high-radix chip-to-chip communication topology (e.g., dragonfly topology, hyperX topology, etc.), such as a topology having greater than or equal to eight chip-to-chip communication links per processor device 701. In some instances, chip-to-chip communication units 712 can include units configured to communicate with processor devices that are geographically close to or far away from the processor device 701 (e.g., in a same or different compute node as the processor device 701; in a same or different rack; etc.). In some instances, chip-to-chip communication units 712 can include connections to a plurality of distinct chips, a plurality of connections to a single chip, or both. In some instances, chip-to-chip communication units 712 can include chip-to-chip communication units 712 associated with one or more bidirectional communication channels, one or more unidirectional communication channels, or both. In some instances, chip-to-chip communication units 712 can include deterministic communication units configured to perform chip-to-chip communication operations (e.g., send operation, receive operation, etc.) at one or more times predetermined by a compiler; deterministic communication units having a known or deterministic timing for one or more data transfer operations; or the like. In some instances, one or more timing units 705 can be used to provide synchronization for one or more processor devices 701 to facilitate deterministic-timing communication between chips.

A peripheral component interconnect express (PCIe) component 713 can include, for example, a communication device configured to facilitate communication between a processor device 701 and one or more other devices (e.g., computing devices; processor devices; data storage devices; auxiliary devices; etc.). In some instances, a PCIe unit 713 can include a communication system conforming to one or more PCIe communication standards (e.g., PCIe 6.0, PCIe 7.0, etc.). Although FIG. 7 depicts a PCIe unit 713, other communication units or communication standards can be used without deviating from the scope of the present disclosure. In some instances, a processor device 701 can include a deterministic processor device 701 configured to communicate non-deterministically via the PCIe unit 713 while maintaining determinism in the functional unit(s) 702 of the processor device 701 (e.g., according to methods described above).

In some instances, control unit(s) 704 can include one or more devices for controlling one or more operations of the functional unit(s) 702, such as device(s) configured to supply one or more control signals (e.g., assembly code or machine code instructions; switching signals, multiplexer selection signals, etc.) to one or more functional unit(s) 702.

In some instances, control unit(s) 704 can include one or more instruction control unit(s) 714 configured to supply computer-executable instruction(s) to one or more functional units. In some instances, an instruction control unit 714 can include a deterministic instruction control unit 714 configured to supply instruction(s) to the functional unit(s) 702 according to a predefined program order determined by the compiler; supply instruction(s) at one or more predefined times (e.g., clock cycles, etc.); or the like. In some instances, an instruction control unit 714 can include hardware configured to fetch (e.g., prefetch, etc.) instruction(s) from memory at a first time (e.g., before the instructions are needed; during a time of off-peak memory usage; at a time predetermined by a compiler; etc.) and provide corresponding instruction(s) to one or more functional unit(s) 702 at a second time (e.g., second time predetermined by the compiler, etc.)

In some instances, instruction(s) provided to a functional unit 702 by an instruction control unit 714 can be the same as or different from a corresponding instruction received by the instruction control unit 714. For example, in some instances, an instruction control unit 714 can include a unit configured to translate one or more compiled instructions (e.g., instructions in a first computing language or format output by a compiler, etc.) to one or more control signals (e.g., instructions in a second language or format; other control signals such as multiplexer selection signals or the like). In some instances, translating compiled instructions can include translating a memory-efficient stored instruction to a plurality of control signals that may include a greater data volume than the memory-efficient stored instruction. For example, in some instances, translating compiled instructions can include retrieving, from a memory functional unit 707, a compiled instruction; and providing, based on the compiled instruction, a plurality of control signals to one or more (e.g., a plurality of) functional units 702 over one or more (e.g., a plurality of) clock cycles. In some instances, a memory-efficient stored instruction can include a multi-operation instruction associated with a plurality of related operations (e.g., operations of a machine-learning model layer such as matrix multiplication, activation functions, convolution, attention, or the like), and the translated control signals can include a plurality of control signals (e.g., lower-level instructions, etc.) for executing the multi-operation instruction. In some instances, an instruction control unit 714 can include hardware configured to receive an instruction comprising one or more timing parameters (e.g., delay amounts, etc.) or repetition parameters, and output control signal(s) to the functional unit(s) 702 to cause the functional units to perform operations according to the timing or repetition parameters (e.g., at a predetermined clock cycle defined by a compiler, etc.). In some instances, the instruction control unit 714 can control a timing or a number of repetitions of the functional unit(s) 702 by sending control signals comprising timing or repetition data, or by sending raw control signals at a specific time or plurality of times configured to cause the functional unit(s) 702 to perform operations according to one or more timing or repetition parameters.

In some instances, timing and synchronization units 705 can include various components configured to perform synchronization operations, such as operations to track or communicate time data (e.g., current clock cycle data, etc.) to one or more functional units 702 or other components of a processor device 701. In some instances, timing and synchronization units 705 can include one or more of: one or more hardware-aligned counters 715, one or more software-aligned counters 716, or other timing or synchronization component.

Hardware aligned counters 715 may be used to establish a time base for electronic circuitry in each processor device 701, such as a clock, for example. Additionally, each processor device 701 may include software aligned counters 716. Software aligned counters 716 may be synchronized, for example, based on one or more computer-executable instructions (e.g., compiled instructions determined by a compiler, etc.). Hardware aligned counters 715 and software aligned counters 716 may be implemented as digital counter circuits, for example, on each integrated circuit (e.g., each processor device 701 or each die thereof, etc.). For instance, hardware aligned counters 715 may be free-running digital counters (e.g., 8-bit counters) on a processor device 701 that are synchronized periodically. Similarly, software aligned counters 716 may be digital counters (e.g., 8-bit counters) that are synchronized based on timing markers triggered by one or more compiled programs.

In some instances, timing and synchronization units 705 can include one or more components 705 for internal synchronization of a plurality of components (e.g., functional units 702, etc.) of a processor device 701; one or more components 705 for external synchronization between a first processor device 701 and one or more other devices (e.g., a plurality of second processor devices 701, etc.); or both.

In some instances, synchronizing a first device (e.g., first processor device 701 or another device) with a second device (e.g., second processor device 701 or another device, etc.) can include, for example, synchronizing one or more hardware aligned counters 715 of the first processor device 701 with one or more hardware aligned counters of the second device. Synchronizing the hardware aligned counters 715 may occur periodically during the operation of each processor device 701 and may occur at a higher frequency than synchronizing software counters 716, for example. Synchronizing hardware counters may include the first device sending a timing reference (e.g., timing bits representing a time stamp) to the second device over a communication channel (e.g., via chip-to-chip communication units 712, etc.). In some instances, a first processor device 701 may send an 8-bit time stamp, for example. In such a scenario, a hardware counter 715 and software counter 716 of the first device may be maintained in sync locally. However, as the hardware counter 715 on a second device is synchronized to the hardware counter 715 on a first device, the software counter 716 on the second device may drift.

In some instances, software aligned counters 716 of a pair of devices can be synchronized by providing, in each of the devices (e.g., as part of a compiled program executed by the devices, etc.), one or more timing markers configured to be sequentially triggered (e.g., at predetermined positions in a compiled program corresponding to particular points of time or particular cycles). In some instances, timing markers in each device may be configured to trigger on the same cycle in each processor device 701. For example, a first program on a first device may trigger a timing marker on the same cycle as a second program on a second device when the devices'hardware aligned counters 715 are synchronized. In some instances, these timing markers may be used to synchronize software counters 716 of both devices. For example, in some instances, timing differences between the timing markers may correspond to a time difference indicative of a degree to which the two devices are out of synchronization, and synchronization can include adjusting a timing of one or more operations based on the time difference. For example, in some instances, a software aligned counter 716 can perform one or more delay operations at each of a plurality of timing markers, and a length of the delay can be adjusted based at least in part on a time difference between the first and second device at the timing marker. However, same-cycle timing is not required; for example, in some instances, a pair of timing markers may be offset by a known number of cycles, which may be compensated for during the synchronization process (e.g., by using different fixed delays, etc.).

In some instances, a timing difference (e.g., number of cycles, etc.) between timing markers may be constrained within a range. For example, a minimum time difference between timing markers in a first and second device may be based on a time to communicate information between the devices (e.g., a number of cycles greater than a message latency), and a maximum time difference between timing markers in the devices may be based on a tolerance of oscillators forming the time base on each processor device 701 (e.g., if the time difference increases beyond a threshold for a given time base tolerance, it may become more difficult or impossible for the processor devices 701 to synchronize for a given fixed delay). The minimum and maximum number of cycles may also be based on the size of a buffer (e.g., a first in first out (FIFO) memory) in each chip-to-chip communication circuit, for example.

In some instances, synchronizing hardware aligned counters 715 of a pair of devices can include sending, by a first device at a first time t₀, a timing reference; and receiving, at a second time t₁ by a second device, the timing reference. In some instances, the latency of such a transmission may be characterized and designed to be a known time delay Δt=t₁-t₀. In such instances, synchronizing the pair of devices can include setting, by the second device, a hardware aligned counter 715 to a value of (t₀+Δt) such that the hardware aligned counters 715 of both devices are synchronized.

In some instances, although the first and second devices can be architecturally similar (e.g., same) or different, synchronizing the devices can include, for example, assigning a first device as a designated sender device to send timing data, and designating a second device as a designated receiver device to receive timing data and adjust a timing of the receiver device's operations based on the timing data.

In some instances, software aligned counters 716 can be synchronized in a manner similar to synchronization of hardware aligned counters 715. For example, in some instances, a software aligned counter 716 can include or implement one or more timing triggers comprising one or more delays (e.g., no-operation (NOP) delays, etc.), wherein a plurality of devices are configured to perform a synchronized delay, such that one or more operations performed after the synchronized delay may be synchronized. For example, in some instances, a first device may send timing data to a second device at t0; and perform a predefined delay operation until t1. A second device may receive the timing data at (t0+Δt); and determine, based on the timing data, an amount of delay (e.g., number of clock cycles, etc.) to cause the second device to resume operations at t1.

In some instances, synchronization can include fine synchronization (e.g., as described above), coarse synchronization, or both. For example, during various points in operation, the first and second processor devices 701 may be far out of sync. For example, during startup or after a restart (collectively, a “reset”), a set (e.g., pair, etc.) of devices may perform a coarse synchronization (e.g., using a 20-bit digital counter, etc.) to bring the time bases close enough so they can be maintained in alignment using the techniques described above (e.g., within a resolution of the hardware and software counters, such as 8 bits).

In some instances, synchronizing a number of devices greater than two can include performing similar operations with more than two devices, such as pairwise synchronizations at staggered times, such as pairwise synchronization of a processor device 701 with each of a plurality of neighbors in a chip-to-chip communication topology at a plurality of respective times; one-to-many (e.g., one-to-all, etc.) broadcasting of timing data; pairwise propagation of timing data between pairs of devices according to a propagation pattern or communication topology; or other mechanism for sending and receiving timing data and updating a timing of operations based on the timing data.

FIG. 8 is a block diagram of an example computing node 822 according to example implementations of aspects of the present disclosure. A computing node 822 can include a plurality of processor devices 801a, b, c, d and one or more shared devices 823 that are shared between two or more processors 801 of the plurality of processors 801. For example, in some instances, shared device(s) 823 can include one or more of: one or more shared memory or storage devices 824; one or more shared networking or communication devices 825; or other shared devices 826.

A shared device 823 can include, for example, any device providing one or more functions (e.g., storage functions, communication functions, etc.) to a plurality of processor devices 801.

A shared memory or storage device 824 can include one or more components for reading, writing, or storing various kinds of data, such as operand data, instruction data, or other data. For example, in some instances, a shared memory or storage device 824 can include non-volatile memory such as one or more solid state drives (SSDs) or other non-volatile storage. As a non-limiting illustrative example, a GroqNode computing node 822 can include a plurality of processor devices 801 (e.g., eight language processing units (LPUs), etc.) and one or more shared SSD cards for non-volatile storage. As another example, in some instances, a shared memory or storage device can include one or more shared external memory modules (e.g., high-bandwidth memory (HBM) modules, dynamic random access memory (DRAM) modules, etc.) that may be shared between a plurality of processor devices 801.

Shared networking/communication devices 825 can include, for example, any device configured to provide one or more communication functions (e.g., internode communication functions, intra-node communication functions) to one or more processor devices 801, such as one or more network interface controllers, Ethernet communication devices, routers, modems, communication ports, communication channels, or other communication devices. As a non-limiting illustrative example, in some instances, a GroqNode computing node 822 can include one or more network interface controller (NIC) cards configured to provide networking functions for the compute node 822 or processors 801 thereof.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.”

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

What is claimed is:

1. A networking panel comprising:
one or more first ports, each first port configured to receive a multi-strand first connector;
a plurality of second ports, each second port configured to receive a second connector; and
a plurality of communication strands collectively connecting each respective first port of the one or more first ports to two or more corresponding second ports of the plurality of second ports.

2. The networking panel of claim 1, further comprising:
a housing configured to be inserted into a server rack.

3. The networking panel of claim 2, wherein a size of the housing is less than or equal to 4RU.

4. The networking panel of claim 3, wherein the size of the housing is less than or equal to 1RU.

5. The networking panel of claim 1, wherein the one or more first ports comprise a plurality of first ports, wherein at least one second port of the plurality of second ports is configured to receive a multistrand second connector, and wherein the plurality of communication strands collectively connects the at least one second port to two or more corresponding first ports of the plurality of first ports.

6. The networking panel of claim 1, wherein the plurality of second ports comprises at least one port configured to receive a first type of connector and at least one port configured to receive a second type of connector, and wherein the communication strands collectively connect at least one first port of the one or more first ports to each of the at least one port configured to receive a first type of connector and the at least one port configured to receive the second type of connector.

7. The networking panel of claim 6, wherein the first type of connector has a first bandwidth, and the second type of connector has a second bandwidth different from the first bandwidth.

8. The networking panel of claim 6, wherein the first type of connector is associated with a first number of strands, and wherein the second type of connector is associated with a second number of strands different from the first number of strands.

9. The networking panel of claim 1, wherein at least one second port of the plurality of second ports is configured to receive a corresponding second connector having a first number of strands, wherein at least one port of the one or more first ports is configured to receive a corresponding multi-strand first connector having a second number of strands, and wherein the first number of strands is different from the second number of strands.

10. A computing system comprising:
a plurality of computing devices; and
one or more networking panels each comprising:
one or more first ports, each first port configured to receive a multi-strand first connector;
a plurality of second ports, each second port configured to receive a second connector; and
a plurality of communication strands collectively connecting each respective first port of the one or more first ports to two or more corresponding second ports of the plurality of second ports;
wherein each computing device of the plurality of computing devices is operatively connected to at least one networking panel of the one or more networking panels.

11. The computing system of claim 10, further comprising a plurality of racks each comprising a plurality of compute nodes, wherein the one or more networking panels are connected to each rack of the plurality of racks via one or more multi-strand communication channels.

12. The computing system of claim 11, further comprising one or more active switches connected to the one or more networking panels.

13. The computing system of claim 12, wherein the one or more active switches are disposed in one or more end-of-row networking racks.

14. The computing system of claim 10, wherein a size of each of the one or more networking panels is less than or equal to 2RU.

15. The computing system of claim 10, wherein the one or more first ports comprise a plurality of first ports, wherein at least one second port of the plurality of second ports is configured to receive a multistrand second connector, and wherein the plurality of communication strands collectively connects the at least one second port to two or more corresponding first ports of the plurality of first ports.

16. The computing system of claim 10, wherein the plurality of second ports comprises at least one port configured to receive a first type of connector, at least one port configured to receive a second type of connector, and wherein the communication strands collectively connect at least one first port of the one or more first ports to each of the at least one port configured to receive a first type of connector and the at least one port configured to receive the second type of connector.

17. The computing system of claim 16, wherein the first type of connector is characterized by a first bandwidth, and the second type of connector is characterized by a second bandwidth different from the first bandwidth.

18. The computing system of claim 16, wherein the first type of connector is associated with a first number of strands, and wherein the second type of connector is associated with a second number of strands different from the first number of strands.

19. The computing system of claim 10, wherein at least one second port of the plurality of second ports is configured to receive a corresponding second connector having a first number of strands, wherein at least one port of the one or more first ports is configured to receive a corresponding multi-strand first connector having a second number of strands, and wherein the first number of strands is different from the second number of strands.

20. A method for wiring a data center, comprising:
connecting each computing device of a plurality of computing devices to a corresponding networking panel of a plurality of networking panels, wherein each networking panel of the plurality of networking panels comprises:
one or more first ports, each first port configured to receive a multi-strand connector;
a plurality of second ports, each second port configured to receive a connector; and
a plurality of communication strands collectively connecting each respective first port of the one or more first ports to two or more corresponding second ports of the plurality of second ports; and
connecting each networking panel of the plurality of networking panels to one or more active switches.
